(19) United States
(12) Patent Application Publication
(10) Pub. No.: US 2026/0150220 A1
(43) Pub. Date: May 28, 2026

(54) LIVING HINGE CABLE BOOT CLIP

(71) Applicant: Molex, LLC, Lisle, IL (US)

(72) Inventors: Hui-Chin Yang, New Taipei City (TW); Tung-Min Chen, New Taipei City (TW); Christopher Richard Pinkham Basa, St. Paul, MN (US); Trevor Dean Smith, Eden Prairie, MN (US); Wenzong Chen, Naperville, IL (US)

(21) Appl. No.: 19/364,356

(22) Filed: Oct. 21, 2025

Related U.S. Application Data
(60) Provisional application No. 63/726,214, filed on Nov. 27, 2024.

(51) Int. Cl. H05K 7/14; F16B 2/22; F16C 11/12

(52) U.S. Cl. CPC H05K 7/1491; F16B 2/22; F16C 11/12

(57) ABSTRACT

A living hinge cable boot clip includes a body comprising a living hinge that separates an upper portion of the body from a lower portion of the body. The upper portion includes a locking member and the lower portion includes a locking detent configured to retain the locking member of the upper portion. The upper portion includes a plurality of upper ribs and the lower portion includes a plurality of lower ribs. Respective ones of the plurality of upper ribs are in alignment with ones of the plurality of lower ribs to define a plurality of cable storage areas configured to retain a plurality of cable boots therein. The living hinge, upper portion, and lower portion are integral with one another and formed of an injection molded polymer material. The cable storage areas are contoured to conform to the geometry of the cable boots and permit float along a Z axis.

### TECHNICAL FILED

The present disclosure relates to cable management devices and, more particularly, to a clip for organizing and constraining multiple cable and other portions using a living hinge design.

### BACKGROUND

Cable management is a critical aspect of many electronic and electrical systems, particularly in environments where multiple cables need to be organized, secured, and protected. As the complexity of systems increases, so does the number of cables required, leading to potential issues with tangling, identification, and maintenance. Cable boots, which are protective covers placed over cable connectors or termination points, are commonly used to provide strain relief and environmental protection. However, managing multiple cable boots in close proximity can present challenges in terms of space efficiency and ease of access.

Existing solutions for organizing multiple cable boots often involve separate clips or fasteners for each individual boot, which can be time-consuming to install and may not provide optimal space utilization. Additionally, such solutions may lack flexibility in accommodating different sizes or configurations of cable boots, or may not allow for easy individual cable manipulation once installed. As electronic systems continue to evolve and miniaturize, there is an ongoing need for cable management solutions that can effectively organize and constrain multiple cable boots while maintaining a compact form factor and allowing for necessary adjustments during installation or maintenance.

### BRIEF SUMMARY

According to an aspect of the present disclosure, a living hinge cable boot clip is provided. The living hinge cable boot clip includes a body comprising a living hinge that separates an upper portion of the body and a lower portion of the body. The upper portion includes a locking member and the lower portion includes a locking detent configured to retain the locking member of the upper portion. The upper portion includes a plurality of upper ribs and the lower portion includes a plurality of lower ribs. Respective ones of the plurality of upper ribs are in alignment with ones of the plurality of lower ribs to define a plurality of cable storage areas configured to retain a plurality of cable boots therein.

The living hinge, the upper portion, and the lower portion may be integral with one another, and may be formed of an injection molded polymer material. Bottom surfaces of each of the plurality of cable storage areas may be contoured to conform to a geometry of the plurality of cable boots. The bottom surfaces of each of the plurality of cable storage areas may be contoured to permit a float of the plurality of cable boots along a Z axis. Each of the plurality of cable storage areas may be configured to retain two or more of the plurality of cable boots. Each of the plurality of cable storage areas may be configured to retain three of the plurality of cable boots. The living hinge cable boot clip may further comprise a release tab extending from the upper portion configured such that, when force is applied in a predetermined direction, causes the locking member of the upper portion to dislodge from the locking detent of the lower portion. The locking member may be configured to form a snap connection with the locking detent. The locking member may comprise a hooked portion, and the locking detent is configured to receive the hooked portion.

According to another aspect of the present disclosure, a cable clip is provided. The cable clip includes a body comprising a flexible portion that separates an upper portion of the body and a lower portion of the body. The upper member and the lower member are pivotable relative to one another via the flexible portion. The upper portion includes a locking member and the lower portion comprising a locking detent configured to retain the locking member of the upper portion. The upper portion and the lower portion collectively define a plurality of cable storage areas that are configured to retain a plurality of cable portions therein. The flexible portion can be a living hinge in some aspects.

The upper portion includes a plurality of upper ribs and the lower portion includes a plurality of lower ribs, and respective ones of the plurality of upper ribs may be in alignment with ones of the plurality of lower ribs to define the plurality of cable storage areas. The flexible portion, the upper portion, and the lower portion may be integral with one another, and may be formed of an injection molded polymer material.

Bottom surfaces of each of the plurality of cable storage areas may be contoured to conform to a geometry of the plurality of cable boots. The bottom surfaces of each of the plurality of cable storage areas may be contoured to permit a float of the plurality of cable boots along a Z axis. Each of the plurality of cable storage areas may be configured to retain two or more of the plurality of cable portions. Each of the plurality of cable storage areas may be configured to retain three of the plurality of cable portions.

The cable clip may further comprise a release tab extending from the upper portion configured such that, when force is applied in a predetermined direction, causes the locking member of the upper portion to dislodge from the locking detent of the lower portion. The locking member may be configured to form a snap connection with the locking detent, or other type of connection. The locking member can include a hooked portion, and the locking detent can be configured to receive the hooked portion. The plurality of cable portions can be a plurality of cable boots.

This summary is provided to introduce a selection of concepts in a simplified form that are further described below in the detailed description, and is not intended to identify key features or essential features of the claimed subject matter, nor is it intended to be used as an aid in determining the scope of the claimed subject matter. The foregoing general description of the illustrative embodiments and the following detailed description thereof are merely exemplary aspects of the teachings of this disclosure and are not restrictive.

### BRIEF DESCRIPTION OF THE DRAWINGS

Many aspects of the present disclosure can be better understood with reference to the following drawings. The components in the drawings are not necessarily to scale, with emphasis instead being placed upon clearly illustrating the principles of the disclosure. Moreover, in the drawings, like reference numerals designate corresponding parts throughout the several views.

FIG. 1 is a top perspective view of a living hinge cable boot clip in a closed state according to various embodiments of the present disclosure.

FIG. 2 is a bottom perspective view of the living hinge cable boot clip according to various embodiments of the present disclosure.

FIG. 3 is another top perspective view of the living hinge cable boot clip according to various embodiments of the present disclosure.

FIG. 4 is another bottom perspective view of the living hinge cable boot clip according to various embodiments of the present disclosure.

FIGS. 5 and 6 are side views of the living hinge cable boot clip according to various embodiments of the present disclosure.

FIG. 7 is a top perspective view of the living hinge cable boot clip in an open state according to various embodiments of the present disclosure.

FIG. 8 is a bottom perspective view of the living hinge cable boot clip according to various embodiments of the present disclosure.

FIG. 9 is a front elevation view of the living hinge cable boot clip storing cable boots therein according to various embodiments of the present disclosure.

FIG. 10 is a top perspective view of the living hinge cable boot clip storing cable boots therein in an open state according to various embodiments of the present disclosure.

FIG. 11 is a top perspective view of the living hinge cable boot clip storing cable boots therein in a closed state according to various embodiments of the present disclosure.

### DETAILED DESCRIPTION

The present disclosure relates to cable clips and, more specifically, to a living hinge cable boot clip for retaining cable boots and other desired cable portions. Due to increasing complexity and miniaturization of electronic systems, effective cable management has become an important aspect of system design and maintenance. Modern electronic devices and systems often incorporate numerous components that require interconnection through various cables and wires. As these systems become more compact and sophisticated, the density of cables within a limited space can increase significantly.

High cable density can lead to several challenges. Closely packed cables can cause electromagnetic interference between signals, potentially degrading system performance. Tightly bundled cables can impede proper airflow, leading to heat buildup that may affect component reliability and lifespan. Crowded and disorganized cables can make it challenging to identify, access, and replace specific components or connections during maintenance or upgrades. Accordingly, various embodiments are described herein for a cable clip that provides organized, secure, and accessible cable arrangements. The cable clip thus contributes to improved system reliability, easier maintenance, and enhanced overall performance of electronic and electrical systems.

The cable clip described herein can include a cable management device for organizing and constraining multiple cable boots or other cable portions in a compact and efficient manner. The cable clip includes a body with a flexible portion, also referred to as a living hinge, that separates an upper portion from a lower portion, allowing the clip to open and close for easy installation and access to cables. The upper and lower portions are equipped with aligned ribs that create cable storage areas, capable of accommodating multiple cable boots or other cable portions.

The cable clip can include a locking mechanism for forming a snap connection or other desirable connection. In some embodiments, the locking mechanism includes a locking member on the upper portion and a corresponding locking detent on the lower portion, ensuring secure closure when in use. The locking member can include a hooked portion that fits into a detent in the locking detent. The clip can also include a release tab on the upper portion, facilitating easy opening when force is applied in a specific direction.

The cable clip can be formed of an injection-molded polymer material and, as such, the cable clip can include a single, integral body that offers durability and flexibility. The cable storage areas of the cable clip can be contoured to match a geometry of cable boots or other cable portions, and can allow for some movement along the Z-axis.

This design provides a versatile solution for managing cables in various electronic and electrical systems, addressing challenges such as tangling, identification, and maintenance while maintaining a compact form factor and allowing for necessary adjustments during installation or maintenance. A cable boot is designed to prevent a cable at an end of a connector from bending sharply, which can cause signal loss. To ensure the connector and cable function correctly and meet industrial standards (e.g., GR-1435-Core), the cable clip as described herein can be removed once any connectors retained therein are mated.

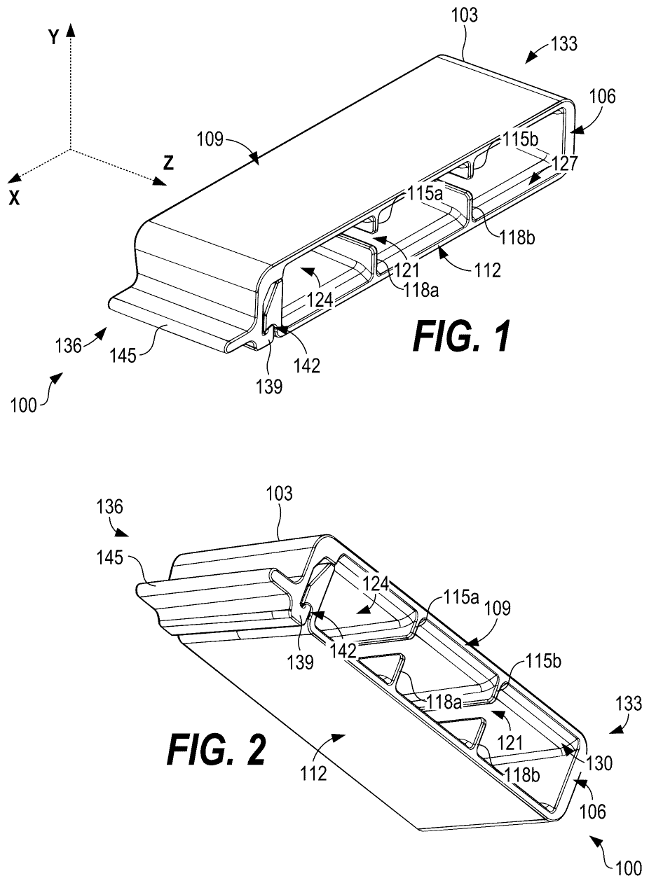

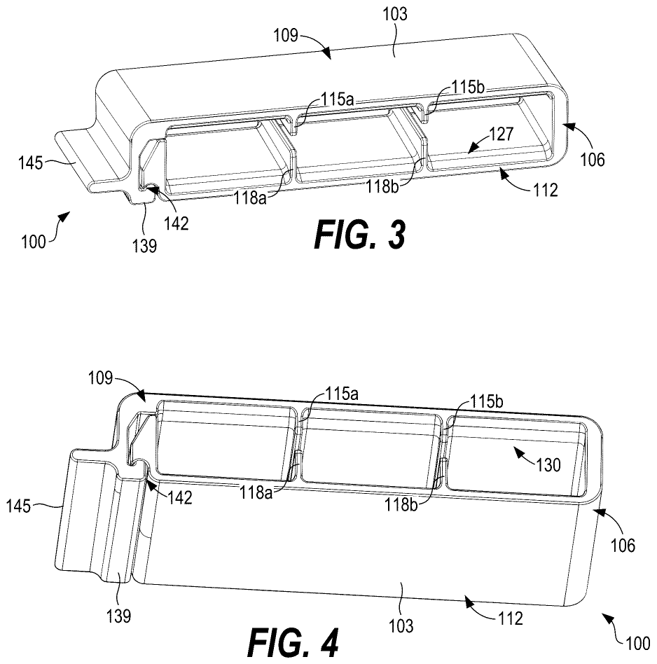

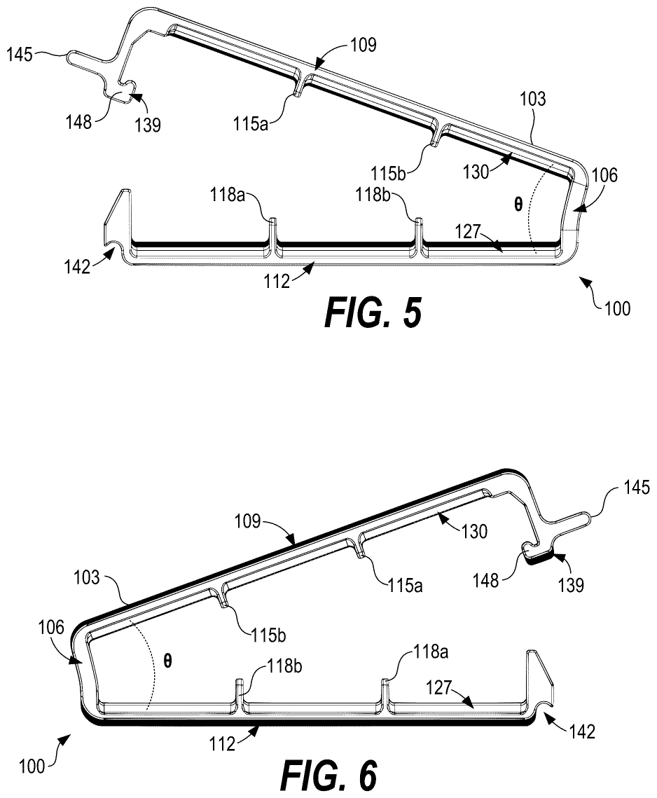

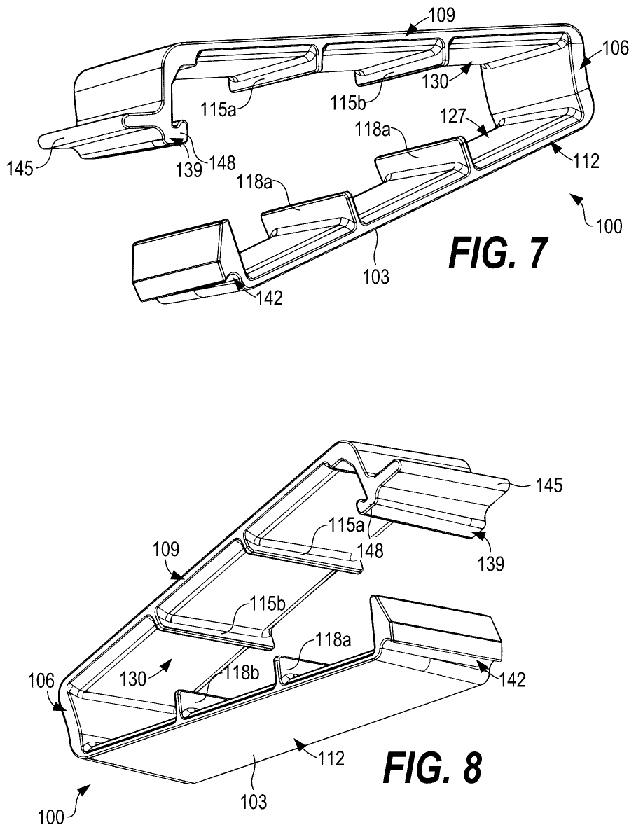

Turning now to the drawings, FIG. 1 shows a top perspective view of a cable clip 100 according to various embodiments of the present disclosure. FIG. 2 is a bottom perspective view, FIG. 3 is another top perspective view, and FIG. 4 is another bottom perspective view of the cable clip 100. FIGS. 5 and 6 are opposing side views of the cable clip 100 according to various embodiments. FIGS. 7 and 8 are top and bottom perspective views, respectively, of the cable clip 100 in an open state according to various embodiments.

Referring to FIGS. 1-8 collectively, the cable clip 100 includes a body 103, also referred to herein as a cable clip body 103. The cable clip body 103 can include a hinge portion or a flexible portion. For instance, in some embodiments, the body 103 can include a living hinge 106, which can include a flexible amount of material that connects two sections of the cable clip body 103, such as an upper portion 109 and a lower portion 112. The living hinge 106 can be formed to allow the upper portion 109 and the lower portion 112 to bend or pivot relative to each other, and can separate the upper portion 109 from the lower portion 112. As such, the living hinge 106 can be formed as a bend between the generally horizontal upper portion 109 and generally horizontal lower portion 112.

In some embodiments, the living hinge 106 can be integrally formed with the upper portion 109 and the lower portion 112 as a single piece, such as from a flexible polymer material. However, a thinness of the living hinge 106 can be different than that of the upper portion 109 and/or the lower portion 112. As such, the thinness of the hinge portion allows the body 103 to flex repeatedly without breaking, while the upper portion 109 and/or the lower portion 112 can remain generally stiff or rigid.

In addition to or alternatively, a flexibility of the living hinge 106 can be enabled based on a different material or a different combination of materials, as compared to the materials of the upper portion 109 and the lower portion 112. For instance, a certain polymer can be used to form the upper portion 109 and/or the lower portion 112, whereas a different polymer can be used to form the living hinge 106. In addition to or alternatively, the flexibility of the living hinge 106 can be enabled by providing one or more notches or detents (not shown) in the living hinge 106.

The upper portion 109 include a lower surface that faces an upper surface of the lower portion 112. The upper portion 109 can include one or more ribs 115a, 115b positioned on the lower surface (collectively “ribs 115” or “upper ribs 115”) and, similarly, the lower portion 112 can include one or more ribs 118a, 118b (collectively “ribs 118” or “lower ribs 118”) positioned on the upper surface. As shown, the upper ribs 115 can be in alignment with the lower ribs 118, where individual upper ribs 115 are positioned directly above individual lower ribs 118 in a one-to-one correspondence. In other words, a first one of the upper ribs 115 is aligned with a first one of the lower ribs 118, a second one of the upper ribs 115 is aligned with a second one of the lower ribs 118, and so forth. In some embodiments, a gap 121 can be provided between the upper ribs 115 and the lower ribs 118. However, in alternative embodiments, the upper ribs 115 may extend downwards to contact the lower ribs 118. While upper ribs 115 and lower ribs 118 are described, in some embodiments, the cable clip 100 may include only ribs on one of the upper portion 109 or the lower portion 112, and not both.

The upper ribs 115 and the lower ribs 118 collectively define one or more cable storage areas 124, which can include channels that extend from a front of the body 103 to a rear of the body 103. The cable storage areas 124 can thus be configured to receive and retain one or more cable portions. In some embodiments, the cable portions include cable boots, which are protective covers provided on the cables. However, the cable storage areas 124 can also be configured to receive and retain other cable portions, such as wires, connector housings, and so forth.

While various embodiments shown in the figures illustrate the upper ribs 115 and the lower ribs 118 it is understood that, in some implementations, the upper ribs 115 and the lower ribs 118 are not provided. To this end, in some embodiments, the upper portion 109 and the lower portion 112 can collectively define a single cable storage area 124 such that a multitude of connector portions can be closely aligned together and encased within the cable clip 100. This can be useful, for instance, when four or more cable connectors are aligned within the cable clip 100 in a single row.

Further, the one or more cable storage areas 124 can include a lower surface 127, which can be the same as the upper surface of the lower portion 112, as well as an upper surface 130. The lower surface 127 and/or the upper surface 130 of the cable storage areas 124 can be contoured in some embodiments. For example, in implementations where the cable storage areas 124 are configured to receive and retain cable boots, the lower surface 127 and/or the upper surface 130 of the cable storage areas 124 can be contoured to match a geometry of the cable boots. In some embodiments, the lower surface 127 and/or the upper surface 130 can be contoured to prevent horizontal translation of the cable boots (or other cable portions), while permitting float or translation (e.g., 5 mm) of the cable in forward and rearward directions (e.g., the Z-direction shown in FIG. 1). In some embodiments, the lower surface 127 and/or the upper surface 130 are generally flat, with sloped front portions and sloped rear portions that correspondingly fit with a cable boot.

The living hinge 106 can be positioned at a first end 133 of the cable clip 100. In some embodiments, the cable clip 100 can include a locking mechanism that, upon sufficient flexing, can transition the cable clip 100 between an open state and a closed state. The locking mechanism can be positioned at a second end 136 of the cable clip 100 according to various embodiments. To this end, the upper portion 109 can include, for example, a locking member 139 and the lower portion 112 can include a locking detent 142. The locking member 139 and the locking detent 142 can be positioned on the second end 136 of the cable clip 100, for instance, opposite the first end 133. The locking member 139 can extend into the locking detent 142, where the locking detent 142 is configured to retain the locking member 139 therein. The locking detent 142 acts as a catch, preventing flexing of the living hinge 106 and/or movement of the upper portion 109 and the lower portion 112 until released.

In some embodiments, the locking member 139 can include a J-shaped hook that extends from the upper portion 109 of the cable clip 100. The J-shaped hook can be configured to nest into the locking detent 142, which can be formed as an oppositely arranged J-shaped recess in the lower portion 112 of the cable clip 100. When engaged, the curved portion of the J-shaped hook on the locking member 139 can interlock with the complementary curved portion of the J-shaped recess of the locking detent 142, creating a secure connection between the upper portion 109 and the lower portion 112 of the cable clip 100. The interlocking J-shaped design can provide a robust closure mechanism that resists accidental opening while still allowing for intentional disengagement when needed. The curvature of the J-shape can also guide the locking member 139 into proper alignment with the locking detent 142 during closure, facilitating easier and more reliable engagement of the locking mechanism.

It is understood, however, that other locking mechanism geometries can be employed. For instance, the locking mechanism of the cable clip 100 that includes, but is not limited to, the locking member 139 and the locking detent 142, can employ various types of connections to secure the upper portion 109 and the lower portion 112 together at the second end 136 of the cable clip 100. For example, the locking member 139 and the locking detent 142 can provide a snap connection, where the locking member 139 includes a protrusion or hook that slightly flexes as it passes through an opening or past a lip in the locking detent 142, then springs back to its original shape to create a secure engagement. This snap connection can provide audible and/or tactile feedback when properly engaged, allowing for quick and easy closure of the cable clip 100. The snap connection can be designed with different levels of engagement force, from a light snap that is relatively easy to open to a more robust connection that requires significant force to disengage.

As another example, the locking mechanism of the cable clip 100 can employ a friction fit, where the locking member 139 is held in place by the tight tolerances and surface friction within the locking detent 142. Alternatively, the cable clip 100 can incorporate a sliding lock mechanism, where the locking member 139 slides into a channel or groove in the locking detent 142 to secure the cable clip 100 closed.

The second end 136 of the cable clip 100 can further include a release tab 145 extending from the upper portion 109. The release tab 145 can be configured such that, when force is applied in a predetermined direction (e.g., upwards towards an upper surface of the upper portion 109 with reference to FIG. 1), causes the locking member 139 of the upper portion 109 to dislodge from the locking detent 142 of the lower portion 112.

The release tab 145 can include a linear or planar structure that projects from a lateral surface of the second end 136 of the body 103. When force is applied to the release tab 145 in the upward direction (or other predetermined direction), leverage is created that helps overcome the resistance of the locking mechanism. This leverage translates the applied force into a movement that pulls the locking member 139 away from its engaged position within the locking detent 142. The design of the release tab 145 can include a textured surface or ergonomic shaping to enhance grip and ease of use. In some embodiments, the locking member 139 and the locking detent 142 can be formed of a flexible polymer material that facilitates the locking member 139 from disengaging from the locking detent 142 through manipulation of the release tab 145.

The release tab 145 can work in conjunction with the living hinge 106 at the opposite end of the cable clip 100. As force is applied to the release tab 145, the living hinge 106 acts as a pivot point, allowing the upper portion 109 to swing away from or pivot relative to the lower portion 112. This coordinated action ensures a smooth opening motion and prevents undue stress on any single part of the body 103 of the cable clip 100. The inclusion of the release tab 145 can allow for quick and easy access to the stored cable boots or other cable portions when necessary. The release tab 145 can thus facilitate frequent access or reconfiguration of cables as required, such as in data centers. The release tab 145 thus balances secure closure with ease of access.

Referring to FIGS. 5 and 6, opposing side views of the cable clip 100 in an open state are shown. Notably, in the open state, the locking mechanism is disengaged, and the living hinge 106 is shown in a flexed or deformed state, where the upper portion 109 and the lower portion 112 pivot relative to one another. Thus, an angle θ between the upper portion 109 and the lower portion 112 is increased, whereas, in the closed state, the angle θ is decreased. As noted above, in some embodiments, the locking member 139 can include a J-shaped hook 148 that extends from the upper portion of the cable clip 100. The J-shaped hook 148 can extend substantially along a width of the body 103, and the J-shaped hook 148 can be configured to nest into the locking detent 142, which can be formed as an oppositely arranged J-shaped recess in the lower portion 112 of the cable clip 100. When engaged, the curved portion of the J-shaped hook 148 on the locking member 139 can interlock with the complementary curved portion of the J-shaped recess of the locking detent 142, creating a secure connection between the upper portion 109 and the lower portion 112 of the cable clip 100.

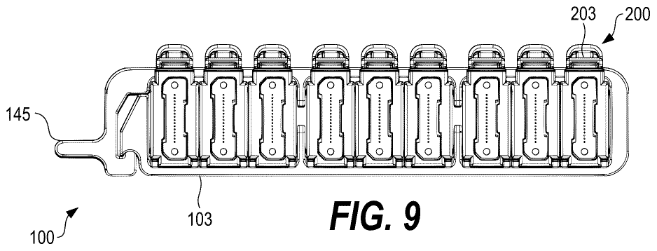

Referring to FIG. 9, a front elevation view of the cable clip 100 is shown having a multitude of connector assemblies 200 stored therein. The cable clip 100 can include multiple cable storage areas 124 arranged in a linear, side-by-side fashion. Each cable storage area 124 can be configured to accommodate one or more cable boots 203 or other cable portions. The release tab 145 provides a mechanism to open the cable clip 100 to insert or remove connectors from the cable clip 100 as needed.

In some implementations, the cable clip 100 can be configured to hold a predetermined number of cable boots 203 or other cable portions. For example, the cable clip 100 can include three distinct sections, each capable of holding one, two, three, or any other desired number of cable boots 203 or other cable portions such as connector housings, wires, or other elements of a cable assembly. In the example shown in FIG. 3, the cable clip 100 includes three distinct sections, where each section retains three cable boots 203 for a total of nine retained cable boots 203.

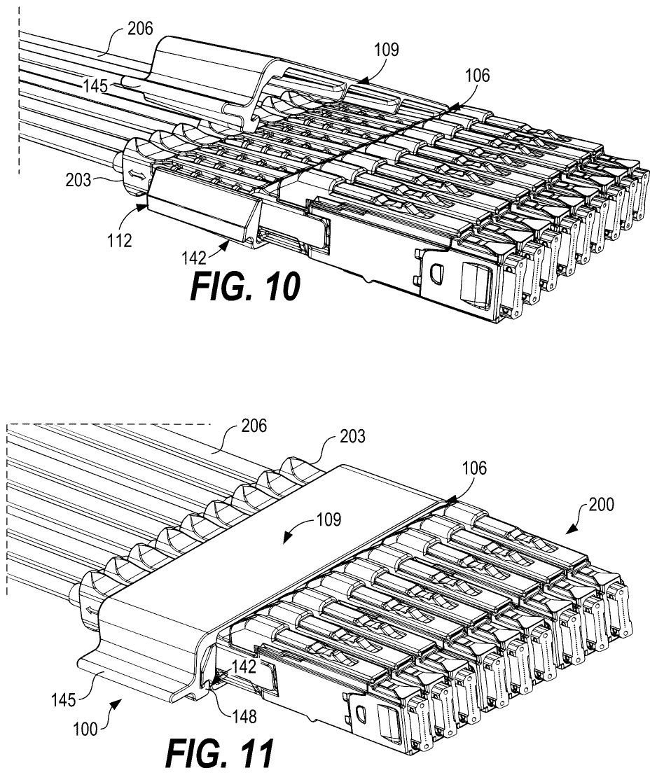

FIGS. 10 and 11 illustrate perspective views of the cable clip 100 in use with a connector assembly 200. In FIG. 10, the cable clip 100 is shown in an open position, with the upper portion 109 lifted away from the lower portion 112, pivoting around the living hinge 106. The open position of the cable clip 100 allows for insertion or removal of cable boots 203 or other cable portions. The lower portion 112 of the cable clip 100 can include multiple cable storage areas 124, each capable of holding three cable boots 203. However, the cable clip 100 can be modified to receive and retain other numbers of cable boots 203 or other cable portions.

The cable boots 203 are visible within the lower portion 112 of the cable clip 100, and three cable boots 203 are retained between the lower ribs 118, where the cable boots 203 serve as protective covers for cable connectors, termination points, and so forth, providing strain relief and environmental protection. In some cases, the cable boots 203 can be part of a larger connector assembly 200, which is visible at one end of the cable clip 100. Wires 206 extend from the cable boots 203. The arrangement of the cable boots 203 and wires 206 within the cable clip 100 allow for organized cable management, potentially reducing tangling, cable stress management, and simplifying identification of specific cables.

FIG. 11 shows the cable clip 100 in a closed position, where the upper portion 109 is engaged with the lower portion 112. In this closed state, the cable boots 203 and associated wires 206 are securely held within the cable storage areas 124. The J-shaped hook 148, which is part of the locking member 139, is shown in the closed position. Specifically, the J-shaped hook 148 is engaged with the locking detent 142 to keep the cable clip 100 securely closed, helping to prevent accidental opening and ensuring that the cable boots 203 and other cable portions remain organized and protected. In both open and closed positions, the connector assembly 200 is visible at one end of the cable clip 100. The cable clip 100 is designed to work in conjunction with specific connector assemblies, potentially allowing for integrated cable management solutions in various electronic or electrical systems. The ability to accommodate different numbers of cable boots 203 or other cable portions in each cable storage area 124 can provide flexibility in cable management for various applications, from simple setups with a few cables to more complex systems with numerous connections.

The cable clip body 103, including the living hinge 106, the upper portion 109, the lower portion 112 (as well as any components thereof), may be formed from a variety of thermoplastic polymers that offer a combination of flexibility, durability, and ease of manufacturing. Suitable materials can include, for example, polyethylene (PE), polypropylene (PP), polyoxymethylene (POM), various grades of nylon (polyamide), and/or any combination thereof. These polymers or combinations can be injection molded to create an integral structure of the cable clip 100, with an area of the living hinge 106 molded to a thinner cross-section to allow for repeated flexing. In some cases, additives such as impact modifiers or reinforcing fibers can be incorporated into the polymer matrix to enhance specific properties like impact resistance or rigidity in the non-hinge areas, such as the upper portion 109, the lower portion 112, the upper ribs 115, the lower ribs 118, and so forth.

In addition to traditional thermoplastics, engineering polymers such as polyetheretherketone (PEEK), polyetherimide (PEI), or polyphenylene sulfide (PPS) can be utilized for applications requiring higher temperature resistance or enhanced chemical compatibility. These materials can offer improved mechanical properties and durability in more demanding environments. Alternatively, thermoplastic elastomers (TPEs) or blends of rigid and flexible polymers can be used to create a cable clip 100 with varying degrees of flexibility in the living hinge 106. In some implementations, multi-material molding techniques can be employed to combine different polymers within a single molded part, allowing for optimization of properties in specific areas of the clip.

The features, structures, or characteristics described above may be combined in one or more embodiments in any suitable manner, and the features discussed in the various embodiments may be interchangeable, if possible. In the following description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although the relative terms such as “on,” “below,” “upper,” and “lower” are used in the specification to describe the relative relationship of one component to another component, these terms are used in this specification for convenience only, for example, as a direction in an example shown in the drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

In this specification, the terms such as “a,” “an,” “the,” and “said” are used to indicate the presence of one or more elements and components. The terms “comprise,” “include,” “have,” “contain,” and their variants are used to be open ended, and are meant to include additional elements, components, etc., in addition to the listed elements, components, etc. unless otherwise specified in the appended claims.

The terms “first,” “second,” etc. are used only as labels, rather than a limitation for a number of the objects. It is understood that if multiple components are shown, the components may be referred to as a “first” component, a “second” component, and so forth, to the extent applicable.

The terms “about” and “substantially,” unless otherwise defined herein to be associated with a particular range, percentage, or related metric of deviation, account for at least some manufacturing tolerances between a theoretical design and manufactured product or assembly, such as the geometric dimensioning and tolerancing criteria described in the American Society of Mechanical Engineers (ASME®) Y14.5 and the related International Organization for Standardization (ISO®) standards. Such manufacturing tolerances are still contemplated, as one of ordinary skill in the art would appreciate, although “about,” “substantially,” or related terms are not expressly referenced, even in connection with the use of theoretical terms, such as the geometric “perpendicular,” “orthogonal,” “vertex,” “collinear,” “coplanar,” and other terms.

The above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

Therefore, the following is claimed:

1. A living hinge cable boot clip, comprising:
a body comprising a living hinge that separates an upper portion of the body and a lower portion of the body, the upper portion comprising a locking member and the lower portion comprising a locking detent configured to retain the locking member of the upper portion,
wherein the upper portion comprises a plurality of upper ribs and the lower portion comprises a plurality of lower ribs, and respective ones of the plurality of upper ribs are in alignment with ones of the plurality of lower ribs to define a plurality of cable storage areas configured to retain a plurality of cable boots therein.

2. The living hinge cable boot clip according to claim 1, wherein the living hinge, the upper portion, and the lower portion are integral with one another and formed of an injection molded polymer material.

3. The living hinge cable boot clip according to claim 1, wherein bottom surfaces of each of the plurality of cable storage areas are contoured to conform to a geometry of the plurality of cable boots.

4. The living hinge cable boot clip according to claim 1, wherein the bottom surfaces of each of the plurality of cable storage areas are contoured to permit a float of the plurality of cable boots.

5. The living hinge cable boot clip according to claim 1, wherein each of the plurality of cable storage areas is configured to retain two or more of the plurality of cable boots.

6. The living hinge cable boot clip according to claim 1, wherein each of the plurality of cable storage areas is configured to retain three of the plurality of cable boots.

7. The living hinge cable boot clip according to claim 1, further comprising a release tab extending from the upper portion configured such that, when force is applied in a predetermined direction, causes the locking member of the upper portion to dislodge from the locking detent of the lower portion.

8. The living hinge cable boot clip according to claim 1, wherein the locking member is configured to form a snap connection with the locking detent.

9. The living hinge cable boot clip according to claim 1, wherein the locking member comprises a hooked portion, and the locking detent is configured to receive the hooked portion.

10. A cable clip, comprising:
a body comprising a flexible portion that separates an upper portion of the body and a lower portion of the body, the upper member and the lower member being pivotable relative to one another via the flexible portion,
wherein the upper portion comprises a locking member and the lower portion comprising a locking detent configured to retain the locking member of the upper portion, and
wherein the upper portion and the lower portion collectively define at least one cable storage area that is configured to retain a plurality of cable portions therein.

11. The cable clip according to claim 10, wherein the at least one cable storage area is a plurality of cable storage areas, the upper portion comprises a plurality of upper ribs and the lower portion comprises a plurality of lower ribs, and respective ones of the plurality of upper ribs are in alignment with ones of the plurality of lower ribs to define the plurality of cable storage areas.

12. The cable clip according to claim 10, wherein the flexible portion, the upper portion, and the lower portion are integral with one another and formed of an injection molded polymer material.

13. The cable clip according to claim 11, wherein bottom surfaces of each of the plurality of cable storage areas are contoured to conform to a geometry of the plurality of cable portions.

14. The cable clip according to claim 11, wherein the bottom surfaces of each of the plurality of cable storage areas are contoured to permit a float of the plurality of cable portions.

15. The cable clip according to claim 10, wherein the at least one cable storage area is configured to retain two or more of the plurality of cable portions.

16. The cable clip according to claim 11, wherein each of the plurality of cable storage areas is configured to retain three of the plurality of cable portions.

17. The cable clip according to claim 10, further comprising a release tab extending from the upper portion configured such that, when force is applied in a predetermined direction, causes the locking member of the upper portion to dislodge from the locking detent of the lower portion.

18. The cable clip according to claim 10, wherein the locking member is configured to form a snap connection with the locking detent.

19. The cable clip according to claim 10, wherein the locking member comprises a hooked portion, and the locking detent is configured to receive the hooked portion.

20. The cable clip according to claim 10, wherein the plurality of cable portions are a plurality of cable boots.
